(19) United States
(12) Patent Application Publication
(10) Pub. No.: US 2008/0174358 A1
(43) Pub. Date: Jul. 24, 2008

(54) Control circuit of P-type power transistor

(75) Inventors: Chen-Fan Tang, Taipei City (TW); Jong-Ping Lee, Hsinchu City (TW)

Correspondence Address: Joe McKinney Muncy, PO Box 1364, Fairfax, VA, 22038-1364, US

(73) Assignee: Winbond Electronics Corp.

(21) Appl. No.: 11/984,776

(22) Filed: Nov. 21, 2007

(30) Foreign Application Priority Data
Jan. 19, 2007 (TW) 96102052

(51) Int. Cl. H03K 17/687

(52) U.S. Cl. 327/434

(57) ABSTRACT

A control circuit for P-type power transistor. The P-type power transistor includes a gate coupled between an input voltage and an output voltage. A first switch is coupled between a first voltage and the gate. A current source provides a first current, and is coupled to a second voltage. A second switch is coupled between the first switch, the gate and the current source. The voltage level of the gate is determined according to the first current when the first switch is turned off and the second switch is turned on.

### BACKGROUND OF THE INVENTION

1. Field of the Invention

The invention relates to a P-type power transistor control circuit, and more particularly to a P-type power transistor control circuit with a soft start function.

2. Description of the Related Art

In general, for power field applications, the size of a power transistor is larger than the size of a metal oxide semiconductor (MOS) transistor in an integrated circuit. Specifically, the power transistor has a larger width to length ratio (W/L). For this reason, parasitic capacitance of the power transistor is larger than the MOS transistor.

$$I = C \frac{d V}{d t} \qquad ( 1 )$$

According to formula (I), other peripheral components may be damaged, due to increase in the instantaneous current from a sudden increase in voltage and the larger parasitic capacitance when the power transistor is turned on. Thus, a soft start scheme is often utilized to avoid any sudden increase in current during the power transistor activation.

Referring to FIG. 1, a control circuit diagram of a conventional N-type power transistor is shown. As shown in FIG. 1, a voltage generated by a charge pump circuit 12 is provided to a gate of an N-type power transistor M11 to turn on the N-type power transistor M11, wherein the output voltage Vₒᵤₜ is substantially equal to an input voltage Vᵢₙ. In FIG. 1, the charge pump circuit 12 is a booster circuit, which transforms an input voltage to an output voltage, wherein the output voltage is higher than the input voltage. In this example, since the output voltage of the charge pump circuit 12 increases slowly, the current flowing through the power transistor decreases.

Compared with N-type power transistors, P-type power transistors are easier to be utilized within integrated circuit design since body effect does not need to consider. However, the charge pump circuit 12 of the N-type power transistor M11 can not be used in the P-type power transistor because the control signal of P-type power transistors are reversed.

Therefore, it is desirable to control the P-type power transistor with a control circuit having the soft start scheme.

### BRIEF SUMMARY OF THE INVENTION

A control circuit for P-type power transistor is provided. An exemplary embodiment of a control circuit for P-type power transistor comprises: a P-type power transistor coupled between an input voltage and an output voltage, having a first gate; a first switch coupled between a first voltage and the first gate; a current source coupled to a second voltage for providing a first current; and a second switch coupled between the current source and a connection point of the first switch and the first gate, wherein a voltage level of the first gate is determined according to the first current when the first switch is turned off and the second switch is turned on.

Another exemplary embodiment of a control circuit for P-type power transistor comprises: a P-type power transistor coupled between an input voltage and an output voltage, having a first gate; a first switch coupled between a first voltage and the first gate; a current source coupled to a second voltage for providing a first current; and a second switch coupled between the current source and a connection point of the first switch and the first gate, wherein a voltage level of the first gate is determined according to a turn-on or turn-off of the second switch.

A detailed description is given in the following embodiments with references to the accompanying drawings.

### BRIEF DESCRIPTION OF DRAWINGS

The invention can be more fully understood by reading the subsequent detailed descriptions and examples with references made to the accompanying drawings, wherein:

FIG. 1 is a control circuit diagram of a conventional N-type power transistor;

FIG. 2 is a control circuit diagram of a P-type power transistor according to an embodiment of the invention;

FIG. 3A is a waveform diagram of control signals of a P-type power transistor shown in FIG. 2;

FIG. 3B is another waveform diagram of control signals of a P-type power transistor shown in FIG. 2;

FIG. 4 is a control circuit diagram of a P-type power transistor according to another embodiment of the invention; and

FIG. 5 is a waveform diagram of control signals of a P-type power transistor shown in FIG. 4.

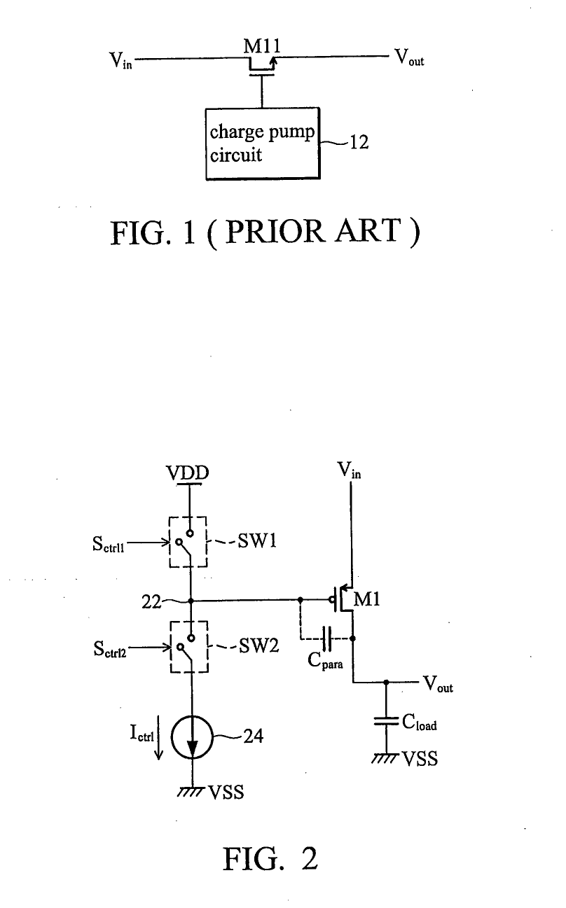

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Referring to FIG. 2, a control circuit diagram of a P-type power transistor according to an embodiment of the invention is shown. A switch SW1 is coupled between a power VDD and a node 22, and a switch SW2 is coupled between a current source 24 and the node 22. The switch SW1 is controlled by a control signal S_{ctrl1} and the switch SW2 is controlled by a control signal S_{ctrl2}, wherein the switch SW1 and the switch SW2 will not be turned on at the same time. The current source 24 is coupled between the switch SW2 and a ground VSS, and provides a current I_{ctrl} to the ground VSS. A gate of a P-type power transistor M1 is coupled to the switches SW1 and SW2 through the node 22. A source of the P-type power transistor M1 is coupled to an input voltage Vᵢₙ, and a drain of the P-type power transistor M1 is coupled to an output voltage Vₒᵤₜ. Moreover, a capacitor C_{load} is an equivalent load of peripheral devices measured from the drain of the P-type power transistor M1, and a capacitor Cₚₐᵣₐ is a parasitic capacitor of the P-type power transistor M1.

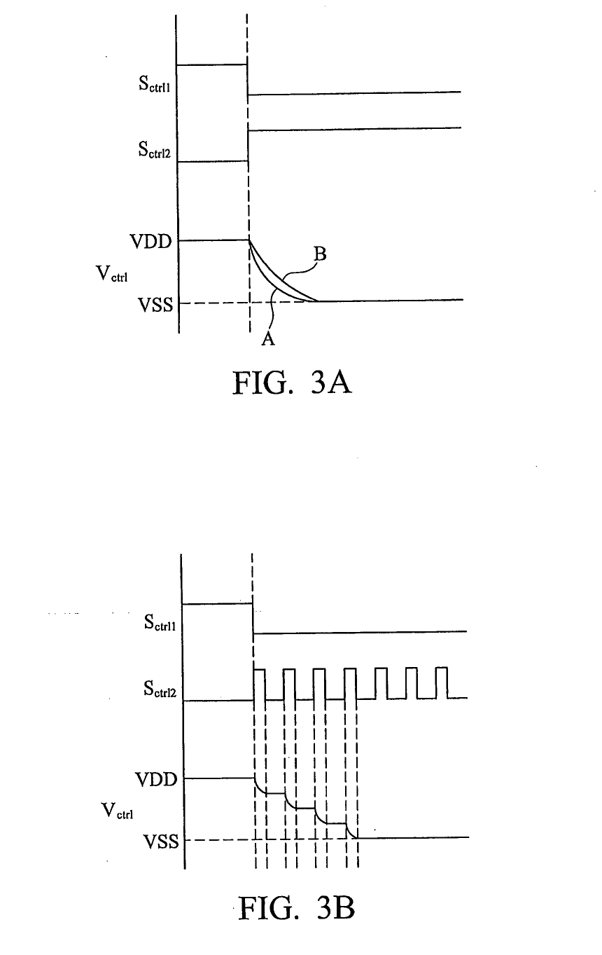

Referring to FIG. 3A, a waveform diagram of control signals of a P-type power transistor shown in FIG. 2, is shown. The switch SW1 is turned on when the control signal S_{ctrl1} is logic “1”. On the other hand, the switch SW1 is turned off when the control signal S_{ctrl1} is logic “0”. Similarly, the switch SW2 is turned on when the control signal S_{ctrl2} is logic “1”, and the switch SW2 is turned off when the control signal S_{ctrl2} is logic “0”. An example for the switch SW1 turned on and the switch SW2 turned off is as follows. The P-type power transistor M1 is turned off when a voltage V_{ctrl} of the node 22 (i.e. a voltage level of the gate of the P-type power transistor M1) is equal to a voltage level of the power VDD. Next, an example for the switch SW1 turned off and the switch SW2 turned on is as follows. It is important to note that the voltage V_{ctrl} stored in the parasitic capacitor Cₚₐᵣₐ is discharged to the ground VSS through the current source 24, wherein a speed of the discharge is determined according to a current amount of the current source 24. The bigger the current I_{ctrl} is, the more quickly the voltage V_{ctrl} is discharged to the ground VSS, as shown in arrow A. On the contrary, the smaller the current I_{ctrl} is, the more slowly the voltage V_{ctrl} is discharged to the ground VSS, as shown in arrow B. The P-type power transistor M1 is turned on when the voltage V_{ctrl} is at a low voltage level, and the output voltage Vₒᵤₜ is substantially equal to the input voltage Vᵢₙ. Meanwhile, the current I_{ctrl} is a predetermined value or is controlled by the current source 24 according to different request in circuit design.

When the P-type power transistor M1 is turned on more slowly, sudden current increases through the power transistor are decreased. Thus, a soft start function of the P-type power transistor M1 is completed. Meanwhile, in addition to the current I_{ctrl}, the soft start of the P-type power transistor M1 may also be controlled by turning on or off the switch SW2.

Referring to FIG. 3B, another waveform diagram of control signals of a P-type power transistor shown in FIG. 2, is shown. A distinction between FIG. 3A and FIG. 3B is that the control signal S_{ctrl2} is a pulse signal, wherein the switch SW2 will not always be turned on. As shown in FIG. 3B, four pulses of the control signal S_{ctrl2} are needed to discharge the voltage V_{ctrl} stored in the parasitic capacitor Cₚₐᵣₐ to a voltage level of the ground VSS. In addition, the turn-on frequency and turn-on time of the switch SW2 are controlled by the pulse frequency and duty cycle of the control signal S_{ctrl2}. Furthermore, a turn-on time of the P-type power transistor is programmed to complete the soft start function according to the current I_{ctrl}.

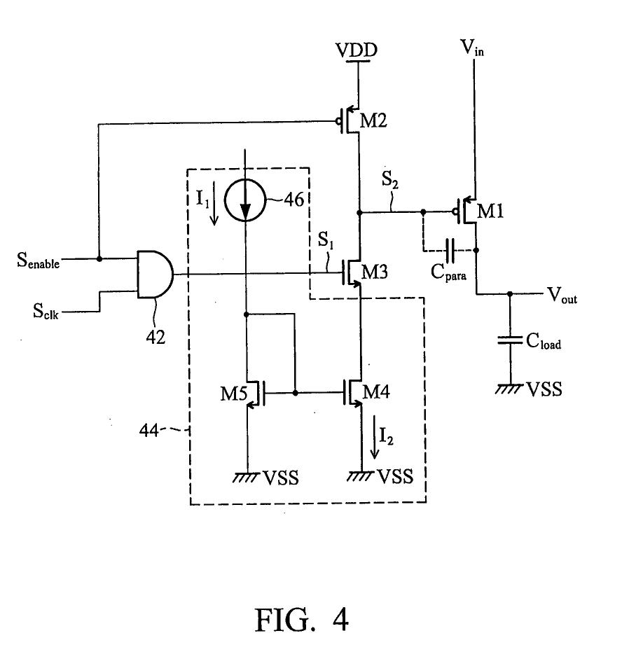

Referring to FIG. 4, a control circuit diagram of a P-type power transistor according to another embodiment of the invention is shown. The source of the P-type power transistor M1 is coupled to the input voltage Vᵢₙ, and the drain of the P-type power transistor M1 is coupled to the output voltage Vₒᵤₜ. The gate of the P-type power transistor M1 is coupled to the drains of transistors M2 and M3. The transistor M2 is a PMOS transistor, which has a source coupled to the power VDD and a gate coupled to an enable signal S_{enable}. The transistor M3 is an NMOS transistor, which has a source coupled to a current mirror 44 and a gate coupled to an output of an AND gate 42. The AND gate 42 generates a pulse signal S₁ to a gate of the transistor M3 according to the enable signal S_{enable} and a clock signal S_{clk}.

The current mirror 44 comprises a current source 46 and two mirror transistors M4 and M5, wherein both the mirror transistors M4 and M5 are NMOS transistor. A drain of the mirror transistors M4 is coupled to the source of the transistor M3. A drain and a gate of the mirror transistor M5 and a gate of the mirror transistor M4 are coupled to the current source 46. Moreover, both the sources of the mirror transistors M4 and M5 are coupled to the ground VSS. The current mirror 44 provides a current I₂ to flow through the mirror transistors M4 according to a current I₁ provided by the current source 46 and the width to length ratio of the mirror transistors M4 to the mirror transistors M5 are as known in the art.

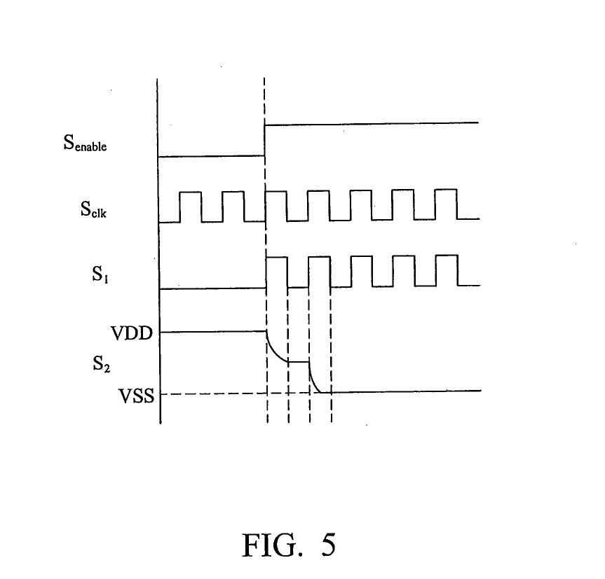

Referring to FIG. 5, a waveform diagram of control signals of a P-type power transistor shown in FIG. 4, wherein a signal S₂ represents a signal obtained from the gate of the P-type power transistor M1, is shown. First, the enable signal S_{enable} is logic “0” and the transistor M2 is turned on. In the meantime, the clock signal S_{clk} is gated by the AND gate 42 such that the pulse signal S₁ is logic “0”. Thus, the signal S₂ is held at the voltage level of the power VDD since the transistor M2 is turned on and the transistor M3 is turned off. Then, the enable signal S_{enable} is changed to logic “1”, the transistor M2 is turned off, and the clock signal S_{clk} is transmitted to the pulse signal S₁ through the AND gate 42. The transistor M3 is turned on when the pulse signal S₁ is logic “1”, and a discharge path is formed from the gate of the P-type power transistor M1 (i.e. the parasitic capacitor Cₚₐᵣₐ) to the ground VSS through the current mirror 44.

A voltage drop of the P-type power transistor M1 is adjusted by controlling the turn-on time or period of the transistor M3 and the current I₂ to control the turn-on time of the P-type power transistor M1. The speed of the discharge is determined according to a frequency or a duty cycle of the clock signal S_{clk}, and the speed is decreased when the frequency is slowed down or the duty cycle is decreased. Therefore, the P-type power transistor M1 is turned on slowly and the soft start function is completed.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A control circuit for P-type power transistor, comprising:
a P-type power transistor coupled between an input voltage and an output voltage, having a first gate;
a first switch coupled between a first voltage and the first gate;
a current source coupled to a second voltage for providing a first current; and
a second switch coupled between the current source and a connection point of the first switch and the first gate, wherein a voltage level of the first gate is determined according to the first current when the first switch is turned off and the second switch is turned on.

2. The control circuit as claimed in claim 1, wherein the voltage level of the first gate is further determined according to a turn-on or turn-off of the first switch and the second switch.

3. The control circuit as claimed in claim 1, wherein a decreased speed of the voltage level is determined according to the first current.

4. The control circuit as claimed in claim 1, wherein the P-type power transistor is turned on according to the voltage level of the first gate.

5. The control circuit as claimed in claim 1, further comprising a first control signal for controlling the first switch and a second control signal for controlling the second switch.

6. The control circuit as claimed in claim 5, wherein the second switch is turned off by the second control signal when the first switch is turned on by the first control signal.

7. The control circuit as claimed in claim 5, wherein the second control signal is a pulse signal.

8. The control circuit as claimed in claim 7, wherein the decreased speed of the voltage level is determined according to a frequency of the pulse signal.

9. The control circuit as claimed in claim 5, further comprising a logic unit for generating the second control signal according to the first control signal and a clock signal.

10. The control circuit as claimed in claim 1, wherein the first switch is a PMOS transistor and the second switch is an NMOS transistor.

11. A control circuit for P-type power transistor, comprising:
a P-type power transistor coupled between an input voltage and an output voltage, having a first gate;
a first switch coupled between a first voltage and the first gate;
a current source coupled to a second voltage for providing a first current; and
a second switch coupled between the current source and a connection point of the first switch and the first gate, wherein a voltage level of the first gate is determined according to a turn-on or turn-off of the second switch.

12. The control circuit as claimed in claim 11, wherein the voltage level is determined according to the first current when the first switch is turned off and the second switch is turned on.

13. The control circuit as claimed in claim 11, wherein a decreased speed of the voltage level is determined according to the first current.

14. The control circuit as claimed in claim 11, wherein the P-type power transistor is turned on according to the voltage level of the first gate.

15. The control circuit as claimed in claim 11, further comprising a first control signal for controlling the first switch and a second control signal for controlling the second switch.

16. The control circuit as claimed in claim 15, wherein the second switch is turned off by the second control signal when the first switch is turned on by the first control signal.

17. The control circuit as claimed in claim 15, wherein the second control signal is a pulse signal.

18. The control circuit as claimed in claim 17, wherein the decreased speed of the voltage level is determined according to a frequency of the pulse signal.

19. The control circuit as claimed in claim 15, further comprising a logic unit for generating the second control signal according to the first control signal and a clock signal.

20. The control circuit as claimed in claim 11, wherein the first switch is a PMOS transistor and the second switch is an NMOS transistor.
